(19) United States
(12) Patent Application Publication
(10) Pub. No.: US 2004/0231592 A1
(43) Pub. Date: Nov. 25, 2004

(54) Apparatus for processing substrate

(76) Inventors: Hiroshi Izawa, Kyoto (JP); Masatoshi Tanaka, Kyoto (JP); Yasuyoshi Takai, Nara (JP)

Correspondence Address: FITZPATRICK CELLA HARPER & SCINTO, 30 ROCKEFELLER PLAZA, NEW YORK, NY, 10112, US

(21) Appl. No.: 10/803,917

(22) Filed: Mar. 19, 2004

(30) Foreign Application Priority Data
Mar. 20, 2003 (JP) 076811/2003(PAT.)
Mar. 15, 2004 (JP) 072107/2004(PAT.)

(51) Int. Cl. C23C 16/00

(52) U.S. Cl. 118/718

(57) ABSTRACT

An apparatus for processing a substrate intermittently transferred includes a transferring unit, including a plurality of rotary rollers for transferring a substrate and also includes at least one removing unit for removing foreign substances present on the curved face of one of the rotary rollers, the rotary roller spaced upstream of a winding unit for winding the substrate.

### BACKGROUND OF THE INVENTION

1. Field of the Invention

The present invention relates to apparatuses for processing substrates, for example, apparatuses for forming a functional layer on a substrate by a deposition method and apparatuses for processing a substrate by a plasma method. The present invention particularly relates to an apparatus for repeatedly processing a substrate continuously for a long time, the apparatus being used for forming solar cells on a long-sized substrate using non-monocrystalline silicon.

2. Description of the Related Art

A CVD method using a roll-to-roll technique is disclosed in U.S. Pat. No. 4,400,409 (hereinafter referred to as Patent Document 1). Such a method is used for processing a substrate in a desired manner, for example, used for forming a functional deposition layer on a substrate or used for processing a substrate by a plasma method.

According to the CVD method, a strip substrate is intermittently fed to a deposition chamber, whereby deposition layers are continuously formed on the substrate. The resulting substrate is transferred in such a manner that the back face of the substrate is in contact with rotary rollers and then coiled. Therefore, if some foreign substances adhere to the back face during the transfer of the substrate, the foreign substances are sandwiched between the back face and the rollers or caught in a gap in the coiled substrate, and the resulting foreign substances cause flaws or deformation in the substrate and also cause flaws or defects in the deposition layers disposed on the substrate. If such foreign substances adhere to the rollers during the transfer of the substrate, the resulting foreign substances cause intermittent flaws or defects extending along the circumference direction of the rollers in the deposition layers because the foreign substances are in contact with the substrate depending on the rotation of the rollers. These problems cause a decrease in equipment efficiency and product yield of manufacturing apparatuses, whereby manufacturing cost is increased.

The following technique is disclosed in Japanese Patent Laid-Open No. 6-260668 (hereinafter referred to as Patent Document 2): a technique for removing foreign substances present on a strip substrate placed in a deposition layer-forming apparatus including a deposition chamber and gas gates. Specifically, the chamber includes a dust-removing unit, placed near an exit thereof, including a blade or brush for removing the foreign substances from the back face of the substrate. The unit prevents flaws or irregularities due to the foreign substances from occurring.

According to this technique, the foreign substances, formed in the chamber, and present on the substrate are removed from the substrate with the unit before the foreign substances arrive at the gas gates, whereby the substrate is prevented from being stuck at the gas gates.

Furthermore, the following technique is disclosed in Japanese Patent Laid-Open No. 6-260421 (hereinafter referred to as Patent Document 3): a technique using one or more dust-removing units, placed in a channel in which a strip substrate is transferred, for removing dust by an antistatic method, the channel being placed outside a region for treating the substrate.

According to this technique, the dust caused to adhere to the substrate by frictional electrification occurring during the transfer of the substrate can be efficiently removed, whereby defects such as flaws due to the dust are prevented from occurring.

Those techniques reduce problems caused by foreign substances present on long-sized substrates, whereby properties and yields of deposition layers disposed on such substrates have been greatly improved.

When deposition layers are formed on a substrate over a long time using a substrate-processing apparatus such as a deposition layer-forming apparatus fit for mass production, foreign substances adhere to the substrate placed in an area other than a deposition chamber. For example, active species diffused from the chamber adhere to the wall of a transfer channel connected to the chamber and accumulate on the wall, whereby layers having a certain thickness are formed in some cases. The layers grow to have a large thickness, and parts of the resulting layers are readily peeled off from the wall and then re-adhere to the substrate in some cases. Furthermore, the deposition layers disposed on the substrate are subject to peeling from the substrate by thermal stress or vibration during the transfer of the substrate in some cases. In addition, fine metal particles are generated by the contact of the transferred substrate with components of the apparatus and fine metal dust arises from rotating or moving components. Such particles and dust are generated in not only the deposition chamber but also a gas gate and/or coiling chamber. The particles and dust may adhere to the substrate.

Those foreign substances generated during the formation of the deposition layers over a long period of time adhere to the strip substrate and rotary rollers and also adhere to an inserting sheet joined to the substrate when the substrate is coiled.

The foreign substances generated in the deposition chamber can be removed by known techniques; however, the foreign substances generated in areas other than the deposition chamber cannot be readily removed. In particular, after the substrate has passed through a known dust-removing unit, the foreign substances adhere to the substrate moving from transfer rollers to rotary rollers placed near a coiling unit and also adhere to the rotary rollers. The resulting foreign substances cause flaws in the deposition layers even when the number of the foreign substances is small.

The foreign substances removed with the dust-removing unit cannot necessarily be prevented from re-adhering to the substrate. That is, when the foreign substances are only removed with the dust-removing unit, the removed foreign substances are caught by the unit and then accumulate near the unit. A large amount of the foreign substances accumulate during the formation of the deposition layers over a long period of time. The resulting foreign substances are caused to rise into a space by gas flows or mechanical vibration and then adhere to the substrate, the inserting sheet, or the rotary rollers. The resulting foreign substances cause flaws and/or defects in the deposition layers in some cases.

In order to prevent problems such as flaws and defects from occurring and in order to prevent problems from occurring during the transfer of the strip substrate, even deposition layer-forming apparatuses having high productivity must be stopped before a large amount of the foreign substances, which re-adhere to the substrate, accumulate. The apparatuses are required to have regular maintenance, wherein the accumulated foreign substances are removed from the apparatuses. Therefore, such maintenance reduces overall equipment efficiency and/or product yield, which prevents cost reduction.

In order to form the deposition layers having little or no flaws and defects on the long-sized substrate over a long period of time with high reproducibility, further improvements must be made.

### SUMMARY OF THE INVENTION

The present invention has been made to solve the above problems. It is an object of the present invention to provide a substrate-processing apparatus having high productivity. When the apparatus is used for processing a substrate over a long period of time, foreign substances are prevented from re-adhering to the substrate, the rotary rollers, and/or an inserting sheet that is in contact with the substrate, whereby flaws or defects are prevented from occurring in the substrate or a processed surface of the substrate.

In the present invention, in order to achieve the above object, an apparatus for processing a substrate intermittently transferred includes a transferring unit, including a plurality of rotary rollers for transferring the substrate and also includes at least one removing unit for removing foreign substances present on the curved face of one of the rotary rollers. The apparatus may further include at least one additional removing unit for removing foreign substances present on the substrate, the additional removing unit spaced upstream of the rotary roller spaced upstream of the winding unit.

In the apparatus, the removing unit preferably includes a first electrifying member for electrifying the removing unit.

In the apparatus, the removing unit may include a contact removing member.

In the apparatus, the removing unit may include a gas-blowing member.

In the apparatus, the removing unit preferably has a surface resistivity of at least 10¹² Ω/sq or a volume resistivity of at least 10¹¹ Ω·cm.

The apparatus may further include a capturing unit for capturing the foreign substances, the capturing unit being independent of the removing unit.

In the apparatus, the substrate and/or the rotary rollers are preferably connected to a diselectrifying member for diselectrifying the substrate and/or the rotary rollers or connected to a second electrifying member for allowing the substrate and/or the rotary rollers to have a potential of a polarity, which is opposite to a polarity of a potential of the foreign substances.

Further objects, features and advantages of the present invention will become apparent from the following description of the preferred embodiments with reference to the attached drawings.

### BRIEF DESCRIPTION OF THE DRAWINGS

FIG. 1 is a schematic view showing a deposition layer-forming apparatus (substrate-processing apparatus) of Example 1.

FIG. 2 is a graph illustrating the relationship between the production of electricity of each sample and the length of a substrate processed with the apparatus of Example 1.

FIG. 3 is a schematic view showing a deposition layer-forming apparatus (substrate-processing apparatus) of Example 2.

FIG. 4 is a schematic view showing a deposition layer-forming apparatus (substrate-processing apparatus) of Example 3.

FIG. 5 is a schematic view showing a deposition layer-forming apparatus (substrate-processing apparatus) of Comparative Example 1.

FIG. 6 is a graph illustrating the relationship between the production of electricity of each sample and the length of a substrate processed with the apparatus of Comparative Example 1.

FIG. 7 is a schematic view showing a deposition layer-forming apparatus (substrate-processing apparatus) of Comparative Example 2.

FIG. 8 is a graph illustrating the relationship between the production of electricity of each sample and the length of a substrate processed with the apparatus of Comparative Example 2.

### DESCRIPTION OF THE PREFERRED EMBODIMENT

An embodiment of the present invention will now be described with reference to the accompanying drawings; however, the present invention is not limited to the embodiment.

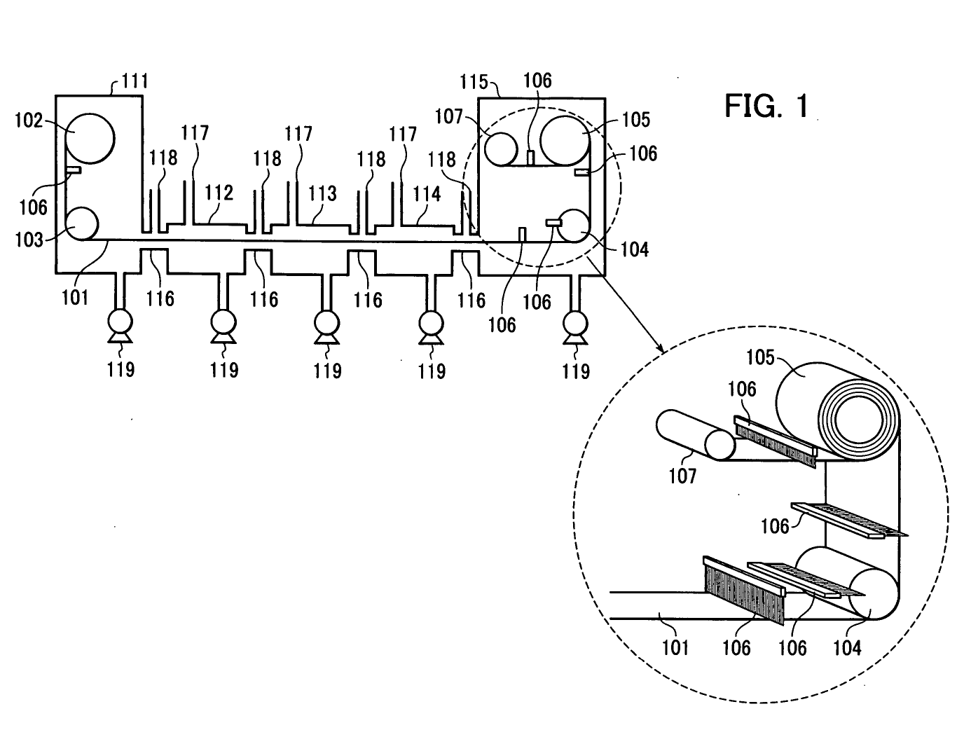

FIG. 1 is a schematic view showing a substrate-processing apparatus according to an embodiment of the present invention.

With reference to FIG. 1, an unwinding coil 102 is placed in a delivery chamber 111, and an elongated strip substrate 101 extends from the unwinding coil 102 through first, second, and third layer-forming chambers 112, 113, and 114, respectively, to a winding chamber 115. Deposition layers are formed on the strip substrate 101 while the strip substrate 101 passes through the first, second, and third layer-forming chambers 112, 113, and 114 in that order. The strip substrate 101 having the deposition layers thereon is wound into a wound coil 105. Before the strip substrate 101 is wound, in order to protect the surfaces of the deposition layers, an inserting sheet 107 is joined to the strip substrate 101 with the deposition layers disposed therebetween. The resulting strip substrate 101 is wound together with the inserting sheet 107.

The first, second, and third layer-forming chambers 112, 113, and 114 and the winding chamber 115 are connected to each other in series in that order with an individual gas gate 116 placed therebetween. These chambers can therefore be isolated from each other. In the first, second, and third layer-forming chambers 112, 113, and 114, different deposition layers are formed on the strip substrate 101, whereby semiconductor layers having, for example, a n·i·p (nip) structure, for solar cells are formed. In FIG. 1, the deposition layers are formed on the lower face of the strip substrate 101.

The first, second, and third layer-forming chambers 112, 113, and 114 each include corresponding deposition gas supply pipes 117, evacuation pumps 119, heaters for heating the substrate, RF power sources for performing discharge, and gas-supplying units so as to form desired deposition layers. The heaters, RF power sources, and gas-supplying units are not shown in the figure. The direction that the strip substrate 101 is transferred is changed with first and second rotary rollers 103 and 104, respectively. The gas gates 116 are each connected to corresponding isolating gas supply pipes 118 through which an isolating gas is supplied. The delivery chamber 111 and the winding chamber 115 are each connected to the corresponding evacuation pumps 119, which evacuate the isolating gas and a gas generated in the chambers.

A procedure for forming the deposition layers using the substrate-processing apparatus of this embodiment will now be described.

The delivery chamber 111 and the winding chamber 115 are evacuated with the evacuation pumps 119, and the isolating gas is then introduced into the gas gates 116 through the isolating gas supply pipes 118. Source gases corresponding to the deposition layers are each introduced into the corresponding first, second, and third layer-forming chambers 112, 113, and 114 through the deposition gas supply pipes 117, and electric discharge is then performed by generating high frequency using the RF power sources. The strip substrate 101 is withdrawn from the unwinding coil 102 placed in the delivery chamber 111 and then led to the winding chamber 115.

In the above operation, the strip substrate 101 is allowed to pass through the first, second, and third layer-forming chambers 112, 113, and 114 in that order; the deposition layers are each formed on the strip substrate 101 in the corresponding first, second, and third layer-forming chambers 112, 113, and 114; and the resulting strip substrate 101 is then wound into the wound coil 105. After the deposition layers having a desired length are formed on the strip substrate 101, the transfer of the strip substrate 101, the discharge, and the gas supply are then stopped.

The atmospheres in the delivery chamber 111 and winding chamber 115 are fully replaced with a purge gas (not shown), and the evacuation pumps 119 are stopped. The wound coil 105 is taken out of the winding chamber 115, a transparent conductive film is formed on the strip substrate 101 withdrawn from the wound coil 105 in the next step (not shown), and the resulting strip substrate 101 is then cut into pieces having a desired size.

According to the above procedure, the deposition layers are completed on the strip substrate 101. In this embodiment, the winding chamber 115 contains foreign substance-removing units 106 for removing foreign substances present or lying on the curved face of the second rotary roller 104, the back face of the strip substrate 101, and the upper and lower faces of the inserting sheet 107.

The foreign substance-removing units 106 of this embodiment are not particularly limited and any removing unit, which can remove and capture the foreign substances without causing pollution or damage in the second rotary roller 104, strip substrate 101, and inserting sheet 107, may be used. The foreign substance-removing units 106 each preferably include corresponding contact removing members such as brush members or blade members because such contact removing members can be uniformly in contact with the second rotary roller 104, strip substrate 101, and inserting sheet 107. The brush members are particularly preferable because the brush members can be electrified or charged by the friction between the brush end and the strip substrate 101, the contact of the brush fibers each other, and the separation of the brush members from the second rotary roller 104, strip substrate 101, and inserting sheet 107. The foreign substances can be efficiently removed via electrostatic attraction generated by the electrification.

Other examples of the contact removing members include rolled sheets that are usually unwound and therefore allowed to provide fresh areas, which are in contact with the foreign substances and efficiently catch them. In particular, the sheets preferably comprise an unwoven fabric, because the foreign substances can be captured by fibers of the unwoven fabric.

In order to enhance the efficiency of removing and capturing the foreign substances by the electrification, the foreign substance-removing units 106 may each include corresponding electrifying members for applying potentials to the contact removing members in addition to potentials generated by the above electrification. The absolute values of potentials applied from the electrifying members are preferably 2 kV or more.

When the first rotary roller 103, the second rotary roller 104, or the strip substrate 101 and the foreign substances are electrified and the foreign substances are securely joined to the first rotary roller 103, second rotary roller 104, or strip substrate 101 before the foreign substances are in contact with the foreign substance-removing units 106, the foreign substances can be efficiently removed by diselectrifying the first rotary roller 103, the second rotary roller 104, or the strip substrate 101 and the foreign substances or allowing them to have a potential opposite to that of the foreign substance-removing units 106 in addition to the use of the foreign substance-removing units 106.

In order to diselectrify the first rotary roller 103, the second rotary roller 104, or the strip substrate 101, a conductive contact member is preferably allowed to contact the first rotary roller 103, the second rotary roller 104, or the untreated face of the strip substrate 101, whereby the first rotary roller 103, the second rotary roller 104, or the strip substrate 101 is grounded.

In order to allow the first rotary roller 103, the second rotary roller 104, or the strip substrate 101 to have a potential opposite to that of the foreign substance-removing units 106, an electrifying electrode may be allowed to be in contact with the first rotary roller 103, the second rotary roller 104, or the untreated face of the strip substrate 101. Alternatively, the first rotary roller 103, the second rotary roller 104, or the strip substrate 101 may be electrified by corona discharge in a non-contact manner using the electrode.

In order to prevent the foreign substances captured by the foreign substance-removing units 106 from re-adhering to the first rotary roller 103, the second rotary roller 104, or the strip substrate 101, a foreign substance-capturing unit such as a tray or inhaling unit is preferably placed between each foreign substance-removing unit 106 and the first rotary roller 103, the second rotary roller 104, or the strip substrate 101.

The foreign substance-removing units 106 may each further include corresponding air-blowing members as desired in addition to the contact removing members. It should be noted that the gas-blowing members must be each placed in corresponding regions which are in, for example, the delivery chamber 111 or the winding chamber 115 and which do not cause problems when gas, for example, inert gas is discharged from the gas-blowing members. Furthermore, it should be noted that the foreign substances removed by the blown gas must be prevented from scattering by the use of, for example, a foreign substance-capturing unit.

In order to prevent flaws from occurring, the foreign substance-removing units 106 preferably comprise a resin such as propylene, Teflon™ brand polytetrafluoroethylene (PTFE), or Viton™ brand copolymer of vinylidene fluoride and hexafluoropropylene which is softer than a material of the strip substrate 101. However, the foreign substance-removing units 106 may contain a hard material, such as glass, having a hardness greater than or equal to that of the strip substrate 101 if the material is processed into a soft member such as a brush or a fiber bundle. The foreign substance-removing units 106 preferably contain a material having a surface resistivity of 10¹² Ω/sq or more or a volume resistivity of 10¹¹ Ω·cm or more.

One of the foreign substance-removing units 106 lying under the strip substrate 101 is preferably placed upstream of a position at which the strip substrate 101 is in contact with the second rotary roller 104. In particular, the foreign substance-removing unit 106 is preferably placed at a position that is close to the unwinding coil 102 and 30 cm or less apart from the contact position.

One of the foreign substance-removing units 106 is preferably in contact with the curved surface of the second rotary roller 104 uniformly in the axial direction. In particular, the foreign substance-removing unit 106 is preferably in contact with a region of the curved surface facing downward because the removed foreign substances can be detached from the foreign substance-removing unit 106 by gravity and prevented from re-adhering to the strip substrate 101 and the like.

Some of the foreign substance-removing units 106 are preferably placed upstream of a position where the inserting sheet 107 meets the wound coil 105. In particular, the foreign substance-removing units 106 are preferably placed at 30 cm or less upstream of the meeting position such that the foreign substance-removing units 106 are arranged on and under the inserting sheet 107.

When the inserting sheet 107 comprises a material such as resin or paper which is readily electrified, bearings of the first and second rotary rollers 103 and 104 comprise resin such as Teflon™ brand PTFE, and the strip substrate 101 has a small thickness, these components are often incompletely grounded. Therefore, when the components are electrified, the adhesion of the foreign substance-removing units 106 to the foreign substances is reduced or the deposition layers are damaged due to static electricity in some cases. Thus, the components are preferably securely grounded.

In this embodiment, the substrate-processing apparatus may further include the dust remover disclosed in Patent Document 2 or 3. The disclosure of Patent Documents 2 and 3 relating to the dust remover is incorporated herein by reference.

According to this embodiment, the foreign substances can be efficiently prevented from adhering to the rotary roller 103 for transferring the strip substrate 101 and the rotary roller 104 placed in the winding chamber 115. The efficiency of removing the foreign substances and the efficiency of capturing the removed foreign substances can be enhanced by electrifying the foreign substance-removing units 106, diselectrifying the strip substrate 101 or the rotary rollers 103 and 104 and the foreign substances, or allowing the strip substrate 101 or the rotary rollers and the foreign substances to have a potential opposite to that of the foreign substance-removing units 106 as required. That is, the foreign substances can be readily removed and then captured with the foreign substance-removing units 106 and the captured foreign substances can be prevented from being detached from the foreign substance-removing units 106 by adjusting the electrostatic attraction between the foreign substances and the strip substrate 101 or the rotary rollers to be less than the electrostatic attraction between the foreign substances and the foreign substance-removing units 106. Therefore, if an external force such as a gas flow or mechanical vibration is applied to the captured foreign substances, the foreign substances can be prevented from being detached from the foreign substance-removing units 106, thereby preventing the detached foreign substances from re-adhering to the strip substrate 101, the inserting sheet 107, or the rotary rollers 103 and 104 and further preventing flows and/or defects due to the foreign substances from occurring in the strip substrate 101 or the deposition layers. Thus, the deposition layers can be formed on a very large scale with high reproducibility.

If the principle of the present invention is applied to deposition layer-forming apparatuses in which deposition can be performed over a long period of time and which have high productivity, the foreign substances can be constantly removed and captured over a long period, whereby deposition layers with little or no defects can be formed. Thus, high-quality deposition layers can be prepared over a long period with high reproducibility, whereby productivity is enhanced and manufacturing cost is reduced.

### EXAMPLES

Examples of the present invention will now be described in detail with reference to the accompanying drawings. The present invention is not limited to the examples.

### Example 1

In this example, deposition layers are formed using an apparatus (substrate-processing apparatus), shown in FIG. 1, for manufacturing amorphous silicon solar cells having a nip (n·i·p) structure on a very large scale. In this apparatus, the deposition layers are formed according to the procedure below. A substrate portion is placed in an n-layer-forming chamber 112 maintained at 350° C.; a monosilane (SiH₄) gas, a hydrogen (H₂) gas, and a phosphine (PH₃) gas are introduced into the n-layer-forming chamber 112 at 250 ml/min, 3,000 ml/min, and 20 ml/min, respectively; and 250 W high frequency is then applied to the substrate portion. The resulting substrate portion is placed in an i-layer-forming chamber 113 maintained at 250° C.; the monosilane gas and the hydrogen gas are introduced into the i-layer-forming chamber 113 at 100 ml/min and 1,000 ml/min, respectively; and 200 W high frequency is then applied to the substrate portion. The resulting substrate portion is placed in a p-layer-forming chamber 114 maintained at 150° C.; the monosilane gas, the hydrogen gas, and a boron trifluoride (BF₃) gas are introduced into the p-layer-forming chamber 114 at 50 ml/min, 4,000 ml/min, and 2 ml/min, respectively; and 1,500 W high frequency is then applied to the substrate portion.

The apparatus has the configuration below. Foreign substance-removing units 106 are each placed at a first position lying between a unwinding coil 102 and a first rotary roller 103. Second position that lies between an inlet of a winding chamber 115 and a second rotary roller 104 and is located 20 cm upstream of the second rotary roller 104, and a third position that lies between the second rotary roller 104 and a wound coil 105, and is located 10 cm upstream of the wound coil 105, such that the foreign substance-removing units 106 are uniformly in contact with the back face of a strip substrate 101. One of the foreign substance-removing units 106 is placed on the second rotary roller 104 such that the foreign substance-removing unit 106 is uniformly in contact with the curved face of the second rotary roller 104. Furthermore, one of the foreign substance-removing units 106 is placed on an inserting sheet 107 such that the foreign substance-removing unit 106 is uniformly in contact with the inserting sheet 107. The foreign substance-removing units 106 each include corresponding polypropylene brush members and are not grounded. The inserting sheet 107 includes a polypropylene film and an aluminum film formed by a deposition method.

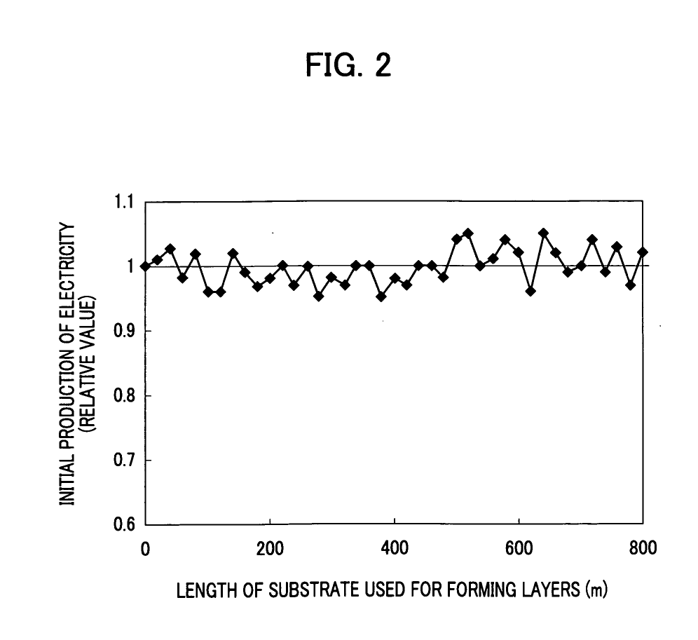

The above procedure for forming the deposition layers was repeated, whereby amorphous silicon layers were formed on the strip substrate 101, made of stainless steel, having a length of 800 m and a width of 35 cm. The resulting strip substrate 101 was cut into pieces having a length of 30 cm and a width of 35 cm. That is, the pieces had an area of 1,050 cm². The pieces were used as samples for evaluating the ability of converting sunlight into electricity. The evaluation results are shown in FIG. 2, which illustrates the relationship between the production of electricity per sample and the length of the strip substrate 101 used for forming the deposition layers. The production is constant with respect to the length; that is, the time spent in forming the deposition layers, as shown in FIG. 2.

The inside of the following chambers was inspected: the n-layer-forming chamber 112, the i-layer-forming chamber 113, the p-layer-forming chamber 114, and the winding chamber 115. The inspection showed that there were a large amount of the captured foreign substances around the foreign substance-removing units 106, but there were no foreign substances on the second rotary roller 104 and the inserting sheet 107. Furthermore, the foreign substance-removing units 106 were measured to determine their potential, which was about −2 kV.

### Example 2

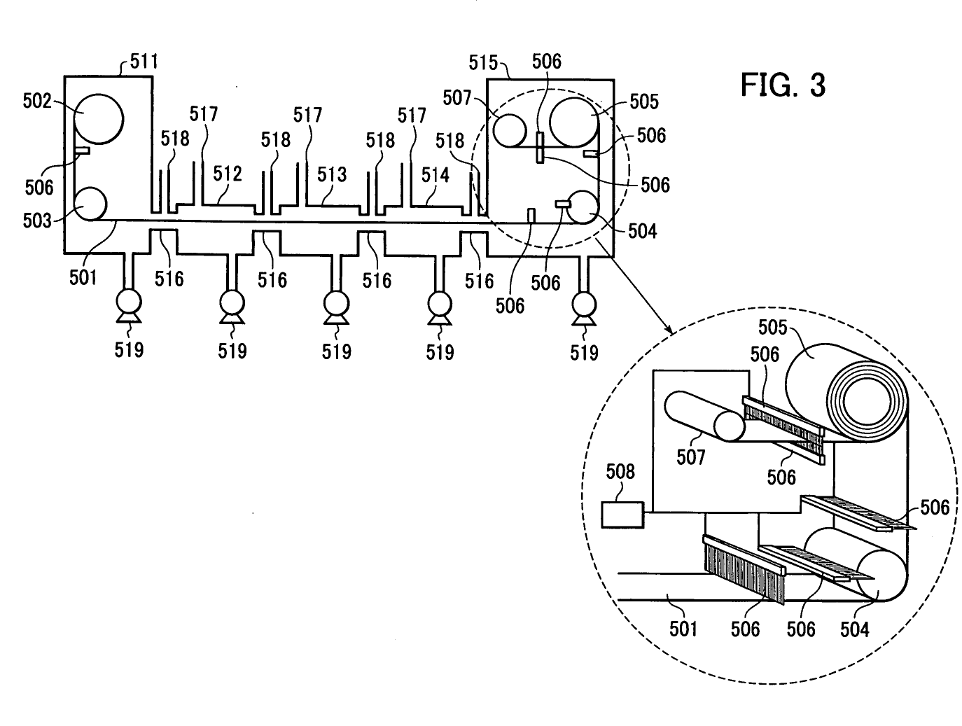

In this example, deposition layers are formed using an apparatus (substrate-processing apparatus), shown in FIG. 3, for manufacturing amorphous silicon solar cells having a nip structure on a very large scale. With reference to FIG. 3, reference numeral 501 represents a strip substrate; reference numeral 502 represents a unwinding coil; reference numerals 503 and 504 represent first and second rotary rollers, respectively; reference numeral 505 represents a wound coil; reference numeral 506 represents foreign substance-removing units; reference numeral 507 represents an inserting sheet; reference numeral 508 represents a high-voltage power supply; reference numeral 511 represents a delivery chamber; reference numeral 512 represents an n-layer-forming chamber; reference numeral 513 represents an i-layer-forming chamber; reference numeral 514 represents a p-layer-forming chamber; reference numeral 515 represents a winding chamber; reference numeral 516 represents gas gates; reference numeral 517 represents deposition gas supply pipes; reference numeral 518 represents isolating gas supply pipes; and reference numeral 519 represents vacuum pumps.

In this apparatus, the deposition layers are formed according to the procedure below. A portion of the strip substrate 501 is placed in the n-layer-forming chamber 512 maintained at 350° C.; a monosilane (SiH₄) gas, a hydrogen (H₂) gas, and a phosphine (PH₃) gas are introduced into the n-layer-forming chamber 512 at 250 ml/min, 3,000 ml/min, and 20 ml/min, respectively; and 250 W high frequency is then applied to the substrate portion. The resulting substrate portion is placed in the i-layer-forming chamber 513 maintained at 250° C.; the monosilane gas and the hydrogen gas are introduced into the i-layer-forming chamber 513 at 100 ml/min and 1,000 ml/min, respectively; and 200 W high frequency is then applied to the substrate portion. The resulting substrate portion is placed in the p-layer-forming chamber 514 maintained at 150° C.; the monosilane gas, the hydrogen gas, and a boron trifluoride (BF₃) gas are introduced into the p-layer-forming chamber 514 at 50 ml/min, 4,000 ml/min, and 2 ml/min, respectively; and 1,500 W high frequency is then applied to the substrate portion.

The apparatus has the configuration below. The foreign substance-removing units 506 are each placed at a first position lying between the unwinding coil 502 and the first rotary roller 503, a second position that lies between an inlet of a winding chamber 515 and the second rotary roller 504 and is located 20 cm upstream of the second rotary roller 504, and a third position that lies between the second rotary roller 504 and the wound coil 505 and is located 10 cm upstream of the wound coil 505 such that the foreign substance-removing units 506 are uniformly in contact with the back face of the strip substrate 501. One of the foreign substance-removing units 506 is placed on the curved face of the second rotary roller 504. The foreign substance-removing units 506 are placed sandwiching the inserting sheet 507 such that the foreign substance-removing units 506 are uniformly in contact with the inserting sheet 507. The foreign substance-removing units 506 each include corresponding Teflon™ PTFE brush members and are connected to the high-voltage power supply 508, which supplies the foreign substance-removing units 506 with a voltage of −5 kV. The inserting sheet 507 comprises an unwoven fabric including aramid fibers.

The above procedure for forming the deposition layers was repeated, whereby amorphous silicon layers were formed on the strip substrate 501, made of stainless steel, having a length of 800 m and a width of 35 cm. The resulting strip substrate 501 was cut into pieces having a length of 30 cm and a width of 35 cm. That is, the pieces had an area of 1,050 cm². The pieces were used as samples for evaluating the ability of converting sunlight into electricity. The evaluation showed that the production of electricity per sample is constant with respect to the length of the strip substrate 501 used for forming the deposition layers. The inside of the following chambers was inspected: the n-layer-forming chamber 512, the i-layer-forming chamber 513, the p-layer-forming chamber 514, and the winding chamber 515. The inspection showed that there were a large amount of the captured foreign substances around the foreign substance-removing units 506, but there were no foreign substances on the second rotary roller 504 and the inserting sheet 507.

### Example 3

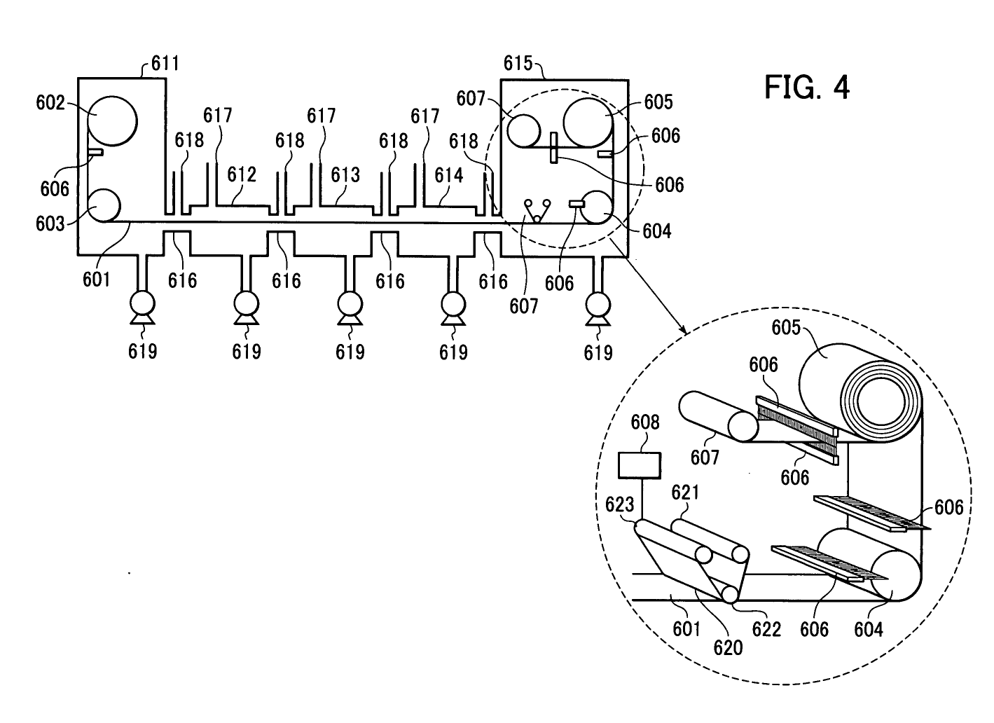

In this example, deposition layers are formed using an apparatus (substrate-processing apparatus), shown in FIG. 4, for manufacturing amorphous silicon solar cells having a nip structure on a very large scale. With reference to FIG. 4, reference numeral 601 represents a strip substrate; reference numeral 602 represents a unwinding coil; reference numerals 603 and 604 represent first and second rotary rollers, respectively; reference numeral 605 represents a wound coil; reference numeral 606 represents foreign substance-removing units; reference numeral 607 represents an inserting sheet; reference numeral 608 represents a high-voltage power supply; reference numeral 611 represents a delivery chamber; reference numeral 612 represents an n-layer-forming chamber; reference numeral 613 represents an i-layer-forming chamber; reference numeral 614 represents a p-layer-forming chamber; reference numeral 615 represents a winding chamber; reference numeral 616 represents gas gates; reference numeral 617 represents deposition gas supply pipes; reference numeral 618 represents isolating gas supply pipes; reference numeral 619 represents vacuum pumps; and reference numeral 620 represents a foreign substance-removing sheet.

In this apparatus, the deposition layers are formed according to the procedure below. A portion of the strip substrate 601 is placed in the n-layer-forming chamber 612 maintained at 350° C.; a monosilane (SiH₄) gas, a hydrogen (H₂) gas, and a phosphine (PH₃) gas are introduced into the n-layer-forming chamber 612 at 250 ml/min, 3,000 ml/min, and 20 ml/min, respectively; and 250 W high frequency is then applied to the substrate portion. The resulting substrate portion is placed in the i-layer-forming chamber 613 maintained at 250° C.; the monosilane gas and the hydrogen gas are introduced into the i-layer-forming chamber 613 at 100 ml/min and 1,000 ml/min, respectively; and 200 W high frequency is then applied to the substrate portion. The resulting substrate portion is placed in the p-layer-forming chamber 614 maintained at 150° C.; the monosilane gas, the hydrogen gas, and a boron trifluoride (BF₃) gas are introduced into the p-layer-forming chamber 614 at 50 ml/min, 4,000 ml/min, and 2 ml/min, respectively; and 1,500 W high frequency is then applied to the substrate portion.

The apparatus has the configuration below. The foreign substance-removing units 606 are each placed at a first position that lies between the unwinding coil 602 and the first rotary roller 603 and is located 10 cm upstream of the first rotary roller 603 and a second position that lies between the second rotary roller 604 and the wound coil 605 and is located 10 cm upstream of the wound coil 605 such that the foreign substance-removing units 606 are uniformly in contact with the back face of the strip substrate 601. One of the foreign substance-removing units 606 is placed on the curved face of the second rotary roller 604. Furthermore, one of the foreign substance-removing units 606 is placed on the inserting sheet 607 such that the foreign substance-removing unit 606 is uniformly in contact with the inserting sheet 607. The foreign substance-removing units 606 each include corresponding polypropylene brush members and are not grounded. The inserting sheet 607 comprises a sheet of paper.

The foreign substance-removing sheet 620 comprises an unwoven fabric, processed into a sheet, including polyester fibers. The foreign substance-removing sheet 620 is withdrawn from a sheet unwinder 621, pressed against the strip substrate 601 with a sheet-pressing bar 622, and then wound around a sheet-winding bar 623. The sheet-pressing bar 622 is placed such that the foreign substance-removing sheet 620 is in contact with the strip substrate 601 at a position located 20 cm upstream of the second rotary roller 604. The foreign substance-removing sheet 620 is wound in the direction that is opposite to the direction that the strip substrate 601 is transferred, whereby foreign substances are captured by the fibers of the unwoven fabric. The sheet-pressing bar 622 is connected to the high-voltage power supply 608, which supplies the sheet-pressing bar 622 with a voltage of −5 kV.

The above procedure for forming the deposition layers was repeated, whereby amorphous silicon layers were formed on the strip substrate 601, made of stainless steel, having a length of 800 m and a width of 35 cm. The resulting strip substrate 601 was cut into pieces having a length of 30 cm and a width of 35 cm. That is, the pieces had an area of 1,050 cm². The pieces were used as samples for evaluating the ability of converting sunlight into electricity. The evaluation showed that the production of electricity per sample is constant with respect to the length of the strip substrate 601 used for forming the deposition layers. The inside of the following chambers was inspected: the n-layer-forming chamber 612, the i-layer-forming chamber 613, the p-layer-forming chamber 614, and the winding chamber 615. The inspection showed that there were a large amount of the captured foreign substances around the foreign substance-removing units 606 and on the foreign substance-removing sheet 620, but there were no foreign substances on the second rotary roller 604 and the inserting sheet 607. The foreign substance-removing units 606 were measured about the potential, which was about −2 kV.

### Comparative Example 1

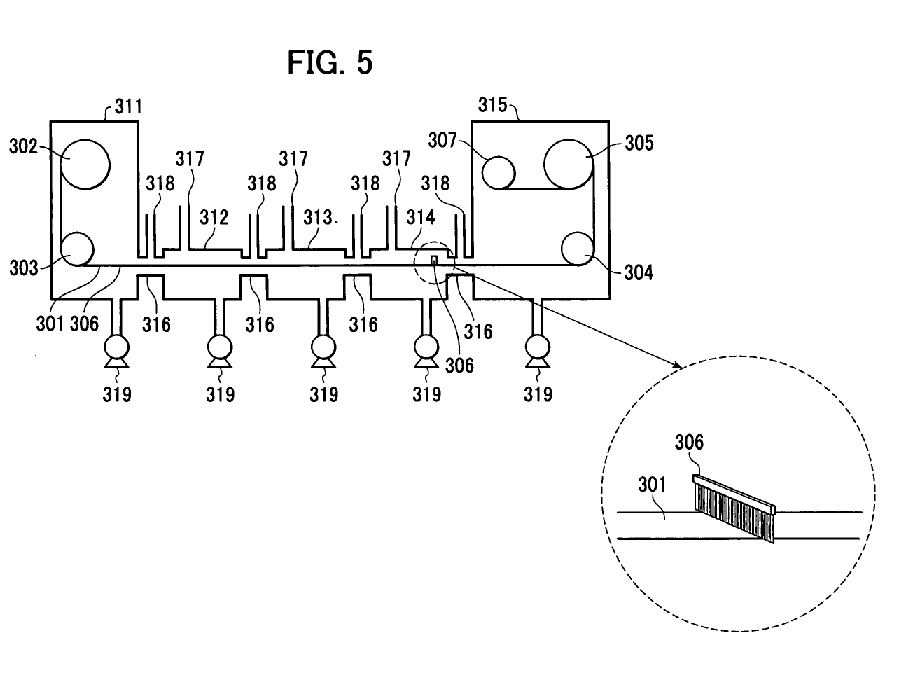

In this comparative example, deposition layers are formed using an apparatus (substrate-processing apparatus), shown in FIG. 5, for manufacturing amorphous silicon solar cells having a nip structure on a very large scale. With reference to FIG. 5, reference numeral 301 represents a strip substrate; reference numeral 302 represents a unwinding coil; reference numerals 303 and 304 represent first and second rotary rollers, respectively; reference numeral 305 represents a wound coil; reference numeral 306 represents a foreign substance-removing unit; reference numeral 307 represents an inserting sheet; reference numeral 311 represents a delivery chamber; reference numeral 312 represents an n-layer-forming chamber; reference numeral 313 represents an i-layer-forming chamber; reference numeral 314 represents a p-layer-forming chamber; reference numeral 315 represents a winding chamber; reference numeral 316 represents gas gates; reference numeral 317 represents deposition gas supply pipes; reference numeral 318 represents isolating gas supply pipes; and reference numeral 319 represents vacuum pumps.

In this apparatus, the deposition layers are formed according to the procedure below. A portion of the strip substrate 301 is placed in the n-layer-forming chamber 312 maintained at 350° C.; a monosilane (SiH₄) gas, a hydrogen (H₂) gas, and a phosphine (PH₃) gas are introduced into the n layer-forming chamber 312 at 250 ml/min, 3,000 ml/min, and 20 ml/min, respectively; and 250 W high frequency is then applied to the substrate portion. The resulting substrate portion is placed in the i-layer-forming chamber 313 maintained at 250° C.; the monosilane gas and the hydrogen gas are introduced into the i-layer-forming chamber 313 at 100 ml/min and 1,000 ml/min, respectively; and 200 W high frequency is then applied to the substrate portion. The resulting substrate portion is placed in the p-layer-forming chamber 314 maintained at 150° C.; the monosilane gas, the hydrogen gas, and a boron trifluoride (BF₃) gas are introduced into the p-layer-forming chamber 314 at 50 ml/min, 4,000 ml/min, and 2 ml/min, respectively; and 1,500 W high frequency is then applied to the substrate portion.

The apparatus has the configuration below. The single foreign substance-removing unit 306 is placed directly upstream of the gas gate 316 located near the outlet of the p-layer-forming chamber 314 such that the foreign substance-removing unit 306 is uniformly in contact with the back face of the strip substrate 301. The foreign substance-removing unit 306 comprises a conductive brush member including carbon fibers.

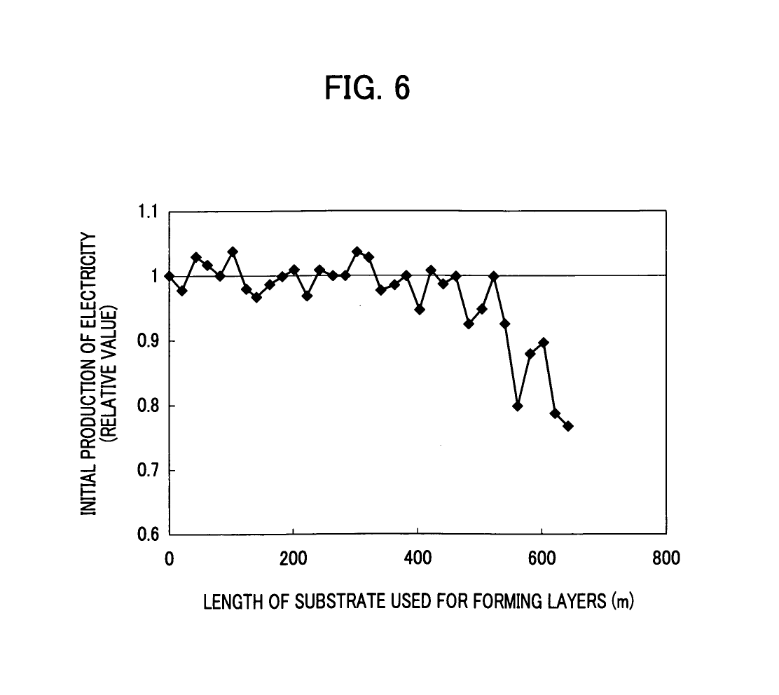

The above procedure for forming the deposition layers was repeated, whereby amorphous silicon layers were formed on the strip substrate 301, made of stainless steel, having a length of 800 m and a width of 35 cm. The resulting strip substrate 301 was cut into pieces having a length of 30 cm and a width of 35 cm. That is, the pieces had an area of 1,050 cm². The pieces were used as samples for evaluating the ability of converting sunlight into electricity. The evaluation results are shown in FIG. 6, which illustrates the relationship between the production of electricity per sample and the length of the strip substrate 301 used for forming the deposition layers. The production declines in reverse proportion to the length.

The inspection of the surface of each sample showed that defects such as the peeling-off of the layers and flaws caused by foreign substances were increased in proportion to the length of the strip substrate 301 used for forming the layers, that is, in proportion to the time spent in forming the layers. The layers having such defects, which are increased in proportion to the time elapsed, do not function sufficiently as solar cells. This is because the functional area of the damaged samples that is effective in generating electricity is smaller than that of the undamaged samples, which have an area of 1,050 cm².

The inside of the following chambers was inspected: the n-layer-forming chamber 312, the i-layer-forming chamber 313, the p-layer-forming chamber 314, and the winding chamber 315. The inspection showed that there was a large quantity of the captured foreign substances around the foreign substance-removing unit 306. Furthermore, there were the foreign substances on the second rotary roller 304 and the inserting sheet 307. This is because the foreign substances accumulated around the foreign substance-removing unit 306 in large quantities were released in the space by mechanical vibration or gas flows and the resulting foreign substances adhered to the second rotary roller 304 and the inserting sheet 307. The foreign substances on the second rotary roller 304 and the inserting sheet 307 caused defects in the layers.

A slip between the strip substrate 301 and second rotary roller 304 was caused by the powdery foreign substances on the second rotary roller 304 when 640 m of the strip substrate 301 was fed. The strip substrate 301 was stuck to a vacuum container, whereby the feed of the strip substrate 301 was stopped. Therefore, the yield of the conforming samples obtained from the strip substrate 301 was about 60%.

### Comparative Example 2

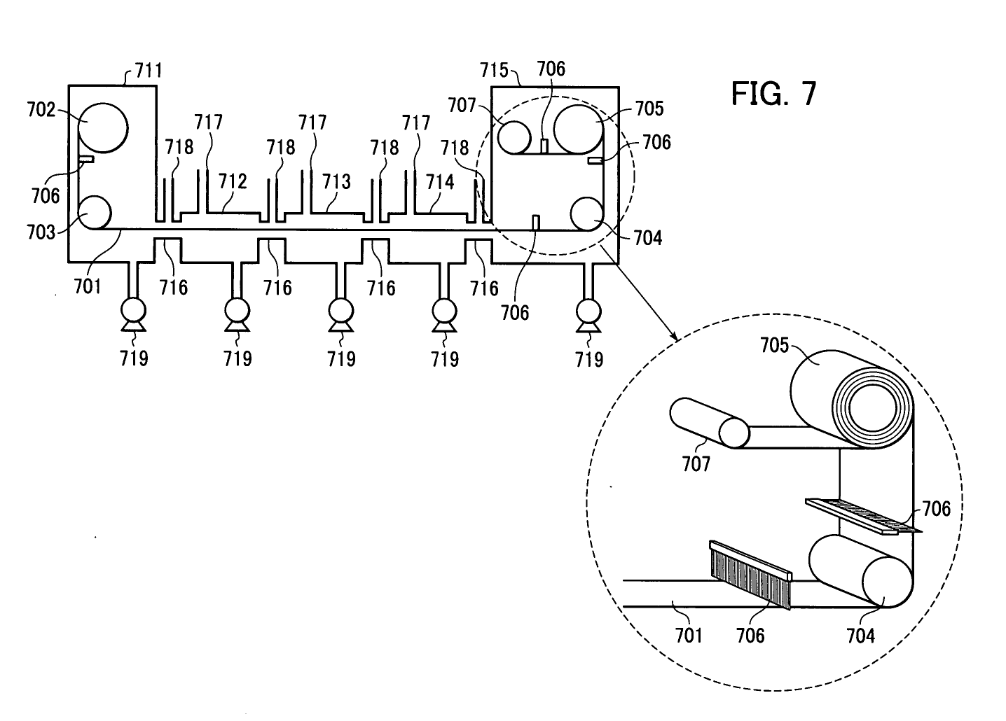

In this comparative example, deposition layers are formed using an apparatus (substrate-processing apparatus), shown in FIG. 7, for manufacturing amorphous silicon solar cells having a nip structure on a very large scale. With reference to FIG. 7, reference numeral 701 represents a strip substrate; reference numeral 702 represents a unwinding coil; reference numerals 703 and 704 represent first and second rotary rollers, respectively; reference numeral 705 represents a wound coil; reference numeral 706 represents foreign substance-removing units; reference numeral 707 represents an inserting sheet; reference numeral 711 represents a delivery chamber; reference numeral 712 represents an n-layer-forming chamber; reference numeral 713 represents an i-layer-forming chamber; reference numeral 714 represents a p-layer-forming chamber; reference numeral 715 represents a winding chamber; reference numeral 716 represents gas gates; reference numeral 717 represents deposition gas supply pipes; reference numeral 718 represents isolating gas supply pipes; and reference numeral 719 represents vacuum pumps.

In this apparatus, the deposition layers are formed according to the procedure below. A portion of the strip substrate 701 is placed in the n-layer-forming chamber 712 maintained at 350° C.; a monosilane (SiH₄) gas, a hydrogen (H₂) gas, and a phosphine (PH₃) gas are introduced into the n-layer-forming chamber 712 at 250 ml/min, 3,000 ml/min, and 20 ml/min, respectively; and 250 W high frequency is then applied to the substrate portion. The resulting substrate portion is placed in the i-layer-forming chamber 713 maintained at 250° C.; the monosilane gas and the hydrogen gas are introduced into the i-layer-forming chamber 713 at 100 ml/min and 1,000 ml/min, respectively; and 200 W high frequency is then applied to the substrate portion. The resulting substrate portion is placed in the p-layer-forming chamber 714 maintained at 150° C.; the monosilane gas, the hydrogen gas, and a boron trifluoride (BF₃) gas are introduced into the p-layer-forming chamber 714 at 50 ml/min, 4,000 ml/min, and 2 ml/min, respectively; and 1,500 W high frequency is then applied to the substrate portion.

The apparatus has the configuration below. The foreign substance-removing units 706 are each placed at a position that lies between an inlet of the winding chamber 715 and the second rotary roller 704 and is located 20 cm upstream of the second rotary roller 704 and another position that lies between the second rotary roller 704 and the wound coil 705 and is located 10 cm upstream of the wound coil 705 such that the foreign substance-removing unit 706 are uniformly in contact with the back face of the strip substrate 701. The foreign substance-removing unit 706 comprises a conductive brush member including carbon fibers.

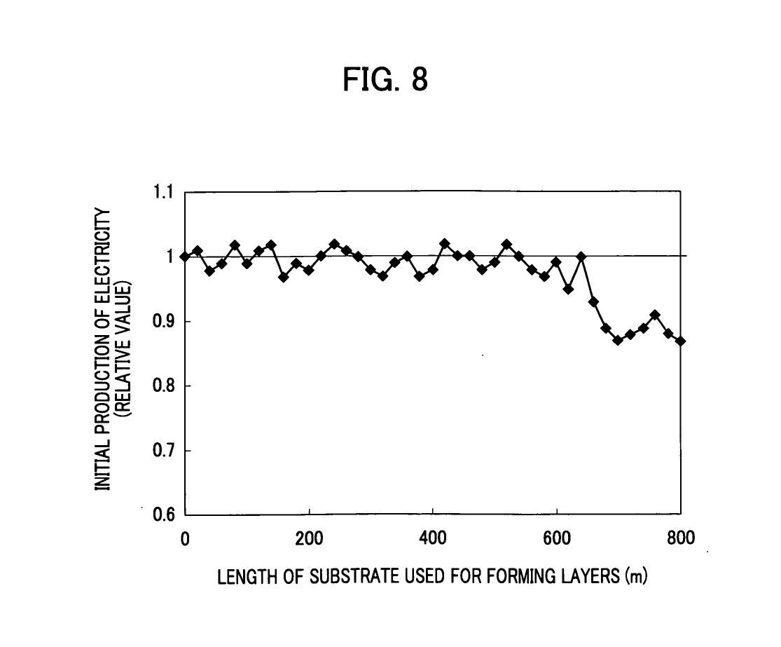

The above procedure for forming the deposition layers was repeated, whereby amorphous silicon layers were formed on the strip substrate 701, made of stainless steel, having a length of 800 m and a width of 35 cm. The resulting strip substrate 701 was cut into pieces having a length of 30 cm and a width of 35 cm. That is, the pieces had an area of 1,050 cm². The pieces were used as samples for evaluating the ability of converting sunlight into electricity. The evaluation results are shown in FIG. 8, which illustrates the relationship between the production of electricity per sample and the length of the strip substrate 701 used for forming the deposition layers. The production declines in reverse proportion to the length.

The inspection of the surface of each sample showed that defects such as the peeling-off of the layers and flaws caused by foreign substances were increased in proportion to the length of the strip substrate 701 used for forming the layers; that is, in proportion to the time spent in forming the layers, in common with Comparative Example 1. The layers having such defects, which are increased in proportion to the processing time, do not function sufficiently as solar cells. This is because the functional area of the damaged samples that is effective in generating electricity is smaller than that of the undamaged samples, which have an area of 1,050 cm².

The inside of the following chambers was inspected: the n-layer-forming chamber 712, the i-layer-forming chamber 713, the p-layer-forming chamber 714, and the winding chamber 715. The inspection showed that there was a large amount of the captured foreign substances around the foreign substance-removing units 706. Furthermore, there were the foreign substances on the second rotary roller 704 and the inserting sheet 707. The samples were inspected in detail, and the inspection showed that the samples had flaws arranged at periodic intervals. The length of each interval was same as the circumference of the second rotary roller 704.

The agreement of the interval length with the circumference of the second rotary roller 704 proves that the foreign substances on the second rotary roller 704 cause the flaws in the deposition layers depending on the rotation of the second rotary roller 704.

Therefore, the yield of the conforming samples obtained from the strip substrate 701 was about 80%.

As described above, according to the present invention, foreign substances can be prevented from adhering to a substrate, a rotary roller, and inserting sheet, which are in contact with the substrate, even if the substrate is processed over a long period of time. Therefore, flaws or defects can be prevented from occurring in the substrate and a processed face thereof. Thus, a substrate-processing apparatus having high productivity can be achieved.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

What is claimed is:

1. An apparatus for processing a substrate intermittently transferred, comprising:
a transferring unit, including a plurality of rotary rollers for transferring a substrate; and
at least one removing unit for removing foreign substances present on the curved face of one of the rotary rollers.

2. The apparatus according to claim 1, further comprising at least one additional removing unit for removing the foreign substances present on the substrate, the additional removing unit spaced upstream of the one of the rotary rollers spaced upstream of the winding unit.

3. The apparatus according to claim 1, wherein the removing unit includes a first electrifying member for electrifying the removing unit.

4. The apparatus according to claim 1, wherein the removing unit includes a contact removing member.

5. The apparatus according to claim 1, wherein the removing unit includes a gas-blowing member.

6. The apparatus according to claim 1, wherein the removing unit has a surface resistivity of at least 10¹² Ω/sq or a volume resistivity of at least 10¹¹ Ω·cm.

7. The apparatus according to claim 1, further comprising a capturing unit for capturing the foreign substances, the capturing unit being independent of the removing unit.

8. The apparatus according to claim 1, wherein the substrate and/or the rotary rollers are connected to a diselectrifying member for diselectrifying the substrate and/or the rotary rollers or connected to a second electrifying member for allowing the substrate and/or the rotary rollers to have a potential of a polarity which is opposite to a polarity of a potential of the foreign substances.

9. The apparatus according to claim 1, wherein the one of the rotary rollers having the removing unit is spaced close to the winding unit.
